(19) United States
(12) Patent Application Publication
(10) Pub. No.: US 2010/0107982 A1
(43) Pub. Date: May 6, 2010

(54) VACUUM DEPOSITION APPARATUS PART AND VACUUM DEPOSITION APPARATUS USING THE PART

(75) Inventors: Michio Sato, Kanagawa-Ken (JP); Takashi Nakamura, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignees: Kabushiki Kaisha Toshiba, Minato-Ku (JP); Toshiba Materials Co., Ltd., Yokohama-shi (JP)

(21) Appl. No.: 12/532,550

(22) PCT Filed: Jul. 11, 2007
(86) PCT No.: PCT/JP07/63812

§ 371 Date: Sep. 22, 2009

(30) Foreign Application Priority Data
Mar. 22, 2007 (JP) 2007-075229

(51) Int. Cl. C23C 14/28; C23C 14/14

(52) U.S. Cl. 118/726; 118/715

(57) ABSTRACT

A vacuum depositing apparatus part constituting a vacuum depositing apparatus for depositing a thin film forming material vaporized in a vacuum chamber on a substrate, the vacuum depositing apparatus part includes: a part body; and a sprayed film integrally formed to a surface of the part body, the sprayed film preferably has a plurality of dimples formed to a surface thereof, and the dimples preferably have an average depth of 10 μm or less. The vacuum depositing apparatus part is capable of stably and effectively preventing a peel-off and dropping-off of a film forming material adhered to the apparatus parts during the film forming operation, capable of suppressing a lowering of productivity of the film product or suppressing an increase of a film forming cost accompanied by a frequent cleaning of the depositing apparatus or a frequent exchange of the apparatus part, and capable of preventing a generation of fine particles.

### TECHNICAL FIELD

The present invention relates to a vacuum deposition apparatus part and a vacuum deposition apparatus using the part which is used to vacuum deposition apparatuses such as a sputtering apparatus, a chemical vapor deposition (CVD) apparatus and the like. Particularly, the present invention relates to a vacuum deposition apparatus part and a vacuum deposition apparatus of which operational management is easy because peeling-off and dropping-off of a film forming material adhered to the part constituting the vacuum deposition apparatus can be prevented for a long time period, and capable of preventing a dropping segment (particle) from mixing into the formed film thereby to form the film having a high quality.

### BACKGROUND ART

In a technical field of electronic parts such as semiconductor part or liquid crystal parts and the like, various fine wiring films or electrode films or the like are formed by utilizing a deposition method (film-forming method) such as sputtering method, CVD method and the like. Concretely, a film forming material is deposited onto substrates such as semiconductor substrate, glass substrate and the like to be formed with a film by utilizing the sputtering method, the CVD method and the like, thereby to form various metal thin films or metal compound thin films. Each of these thin films is used as a wiring layer, an electrode layer, a barrier layer, a primer layer (liner member) and the like.

By the way, in the above vacuum deposition apparatuses such as the sputtering apparatus or the CVD apparatus and the like used for forming the metal thin films or the metal compound thin films, it is unavoidable for various parts provided within the deposition apparatus to be adhered or piled up with the film forming material during a film forming step. The film forming material adhered or piled up to the constituting parts peels off or drops off from the part as time elapses during the film-forming step, thus constituting a factor of generating the particles. When a dust, so called particle, is mixed into the substrate formed with the film, there are disadvantageously caused wiring defects such as “short” (short circuit) and “open” (disconnection) or the like, so that a normal operation of an electronic device is harmed, thus resulting into lowering a production yield of the electronic device.

In view of the above problems, there has been actually adopted a countermeasure in a conventional sputtering apparatus such that a film composed of material having the same or similar thermal expansion coefficient as that of a target material is formed onto a surface of the apparatus constituting parts such as an adhesion prevention plate, a target fixing part and the like, thereby to prevent the peeling-off of the adhered or piled substances (refer to, for example, patent documents 1, 2).

In addition, regarding to the method of forming the film to the surface of the part, various countermeasures have been proposed. In particular, a spraying method has been widely adopted because of its excellence in a contacting property (firmly bonding property) of the film with respect to a part body and an adhesion property of the film forming material. Due to this film formed to the surface of the part, the peeling-off or the dropping-off of the film-forming material (adhered substance) adhered or piled on the apparatus constituting parts are prevented at present technical state.

Surely, according to the above conventional countermeasure for preventing the peeling-off of the adhered substances by providing the films, an effect of decreasing the generation of the particles can be obtained to some extent. However, for example, in a case where a long life is aimed and achieved by forming a metal thin film or a compound film, the following tendency is observed. That is, as an amount of an adhered film adhered on the sprayed film increases, a film projection is formed to the adhered film due to a surface irregularity of the sprayed film. Then, there is formed and exposed a configuration in which extremely fine grains are unstably piled up at a portion around the film projection. When a thermal change caused by plasma is applied to the fine grains, there is a tendency that the fine grains are dropped off and cause the particle generation.

In particular, at a portion where the sputtered grains are deposited from an oblique direction, the irregularity of the sprayed film facilitates the formation of the film projection more remarkably, so that it goes into a state where the particles are liable to be generated. Therefore, as the thickness of the adhered film is increased, the film projection is largely grown thereby to facilitate the particle generation. In addition, an internal stress of the adhered film is increased, and a stress is concentrated to a projective step portion of the sprayed film due to a film stress, so that the projective step portion cannot stand the concentrated stress thereby to generate the particle. Then, an amount of the generated particles is increased and the sprayed film is peeled off together with the adhered film, thus resulting in a situation that it becomes necessary to frequently clean or replace the parts, so that the apparatus part having a long life cannot be achieved.
Patent Document 1: Japanese Patent Publication (Unexamined) No. 2004-83960
Patent Document 2: Japanese Patent Publication (Unexamined) No. 2004-232016

As described above, according to countermeasures for stably piling the adhered substances for preventing the peeling-off of the film in the structural parts constituting the conventional vacuum depositing apparatus, there have been posed problems such that it is not possible to decrease the particles generated from the film forming material (adhered substance) when a Ti film or a TiN film is deposited, and it is not also possible to sufficiently suppress the peeling off of the film, so that the particle generation and the peeling-off of the adhered substance are arisen in a relatively short period of time. When the amount of the generated particles is increased or the peeling-off of the adhered substance causes, it becomes necessary to clean the apparatus or replace the part, so that a work load of the maintenance work for the depositing apparatus is disadvantageously increased, thus resulting in lowering the productivity of the product using the film and increase of the deposition cost.

Further, in a recent semiconductor element (chip), a narrowing of wiring width has been advanced for the purpose of achieving a high integration degree, the wiring width is narrowed to be, for example, from 0.18 μm or 0.13 μm to 0.09 μm or less. In the narrowed wiring or the semiconductor element (chip) having the narrowed wiring, even if an extremely small grain (fine particle) having a diameter of, for example, about 0.2 μm is mixed into the wiring or chip, a wiring defect and a chip defect are disadvantageously occurred. It has been eagerly demanded that the generation of the fine particles caused from the apparatus parts should be further prevented.

Concretely, in the conventional vacuum depositing apparatus disclosed in the patent document 2 (Japanese Patent Publication (Unexamined) No. 2004-232016), since the wiring depth is about 0.25 μm, a coarse particle having a diameter of 0.2 μm or more is recognized as a defect-generating factor. Therefore, in order to eliminate an influence of the particles, a coarse sprayed film having a surface roughness Ra of 30 μm or more and 80 μm or less is formed in the conventional apparatus.

However, in accordance with a further high integration of the semiconductor element in recent days, an ultra fine wiring having a wiring width of 0.13 μm or less has been in practical use. In this extremely fine wiring, there has been posed a practical problem such that the wiring defect and the element defect are liable to cause by the fine particle having a diameter of 0.2 μm or less to which attention has not been conventionally paid. That is, although it is necessary to decrease the fine particles each having a diameter of 0.1 μm or more in order to prevent the wiring defect and the element defect, since the conventional part is formed with the coarse sprayed film having a surface roughness Ra of 30 μm or more and 80 μm or less, the generation of the particle having a diameter of about 0.1 μm cannot be sufficiently suppressed, thus being the practical problem.

### DISCLOSURE OF THE INVENTION

The present invention has been achieved to solve the above conventional problems, and an object of the present invention is to provide a vacuum deposition apparatus part capable of stably and effectively preventing the depositing material adhered to the apparatus parts from being peeled-off or dropped-off during the depositing process in which a thin film constituting a barrier layer composed of, for example, Ti film and TIN film, capable of suppressing an increase of a depositing cost and a lowering of productivity of the film products caused by cleaning of the apparatus and frequent replacement of the parts constituting the apparatus, and further capable of suppressing to generate fine particles. Another object of the present invention is to provide a vacuum deposition apparatus using the part capable of suppressing a mixing of the particles into the deposited film thereby to cope with a highly integrated semiconductor element, and capable of decreasing the depositing cost by improving an operating rate of the depositing operation.

To achieve the above objects, the present invention provides a vacuum depositing apparatus part constituting a vacuum depositing apparatus for depositing a thin film forming material vaporized in a vacuum chamber on a substrate, the vacuum depositing apparatus part comprises: a part body; and a sprayed film integrally formed to a surface of the part body wherein the sprayed film has a surface roughness of 10 μm or less in terms of an arithmetical average surface roughness Ra.

According to the above vacuum depositing apparatus part, since the sprayed film integrally formed on the surface of the part body has the surface roughness of 10 μm or less in terms of an arithmetical average surface roughness Ra, a film forming material (adhered substance) adhered to the surface of the part has an excellent close-contacting property (bonding property) and the peeling-off of the film forming material can be effectively prevented, so that the generation of the particles is reduced and it becomes possible to reduce the wiring defects and element defects, thereby to greatly improve a production yield of electronic parts. Further, since the peeling-off of the film forming material can be effectively suppressed for a long time period, it becomes also possible to reduce a frequency of cleaning the depositing apparatus and a frequency of exchanging the constitutional parts of the depositing apparatus, so that it becomes extremely easy to perform an operation management for the depositing apparatus whereby the productivity of the film products can be increased and the depositing cost can be also reduced.

When the surface roughness of the sprayed film integrally formed on the surface of the part body exceeds 10 μm, a film projection is liable to be formed to the adhered film due to surface irregularities of the sprayed film. Then, there is formed and exposed a configuration in which extremely fine grains are unstably piled up at a portion around the film projection. When a thermal change caused by plasma is applied to the fine grains, there is a tendency that the fine grains are dropped off and cause the particle generation. Accordingly, the surface roughness Ra of the above sprayed film is set to 10 μm or less. However, a range of 5-8 μm is more preferable.

Further, in the above vacuum depositing apparatus part, it is preferable that the sprayed film has a plurality of dimples formed to a surface of the sprayed film. Furthermore, it is also preferable that the dimples have an average diameter of 50 to 300 μm and the dimples have an average depth of 5 to 30 μm. When a shape and number of these dimples are controlled, the surface roughness of the sprayed film can be adjusted to an appropriate range. In addition, as described later on, the above dimples are preferably formed by conducting a plastic work to the surface of the sprayed film.

The surface roughness Ra of the sprayed film ca be controlled to be 10 μm or less within the ranges of the above average diameter and the average depth of the dimples.

The above average diameter and the average depth of the above dimples can be measured through a method comprising the steps of: observing a photograph showing a cross-sectional structure of the sprayed film; arbitrary selecting five dimples adjacent to each other; measuring a diameter and a depth of each of the five dimples; and averaging the measured values.

Further, in the above vacuum depositing apparatus part, it is preferable that the sprayed film is made from any one of Cu, Al and Cu—Al alloy. The above Cu, Al and Cu—Al alloy have a thermal expansion coefficient similar to that of the film forming material. Therefore, even if a thermal history is applied to the film forming material adhered and piled onto the surface of the sprayed film, the peeling-off and dropping-off of the adhered and piled substance due to the difference in thermal expansion coefficient between the two members are few. Accordingly, it can be effectively prevented the product defect caused by mixing the particles into the deposited film.

In this connection, as the above Cu—Al alloy, although a composition of the alloy is not particularly limited, an alloy having a composition containing 10 to 95 mass % of Cu and a balance of Al can be used. As the other components, Si, Zn, Fe, Ni, Mn may be contained in the alloy at amount of about 1 to 2 mass % for improving mechanical property, cutting property, heat resistance or the like.

Further, in the above vacuum depositing apparatus part, it is preferable that the sprayed film has a structure including grains having an average grain size of 5 to 150 μm, and a relative density of the sprayed film is 75 to 99%.

A vacuum depositing apparatus according to the present invention comprises: a vacuum chamber;

a substrate holding portion provided within the vacuum chamber so as to hold a substrate to be formed with a film;

a deposition source provided within the vacuum chamber so as to oppose to the substrate holding portion;

a deposition source holding portion provided within the vacuum chamber so as to hold the deposition source; and

an adhesion preventing portion provided to a portion between the substrate holding portion and the deposition source in the vacuum chamber;

wherein a deposition surface of at least one member selected from the group consisting of the substrate holding portion, the deposition source holding portion and the adhesion preventing portion is formed with a sprayed film having a structure including grains having an average grain size of 5 to 150 μm and the sprayed film has a relative density of 75 to 99%.

Particularly, when the vacuum depositing apparatus is an apparatus for depositing a film composed of Ti or compound thereof, a notable effect of reducing the particles can be exhibited. Example of Ti compound may include TiN (titanium nitride) or the like. This TiN film is formed through a reaction sputtering method in which a Ti target is sputtered in a vacuum atmosphere having a pressure of 1 Pa or lower to which a predetermined amount of N₂ gas is introduced as an atmospheric gas.

In a conventional vacuum depositing apparatus part to which Ti or Ti compound is adhered, for the purpose of increasing the close-contacting property and preventing the peeling-off of the adhered component, the surface roughness Ra of the sprayed film has been set to 30 μm or more as disclosed in the Patent Document 2.

However, in a surface of the vacuum depositing apparatus part for forming the Ti film or TiN film, it has been confirmed to be extremely effective to provide a Cu—Al alloy sprayed film having a small surface roughness Ra of 10 μm or less.

Further, in the above vacuum depositing apparatus part, it is preferable that the sprayed film has a thickness of 50 μm or more. When the thickness of the sprayed film is excessively small to be less than 50 μm, a function of mitigating the difference in thermal expansion coefficients between the sprayed film and the adhered and piled film-forming material is lowered, so that the film-forming material adhered and piled to the part is liable to peel-off or drop-off thereby to increase an amount of particles mixed into the deposited film. Accordingly, the thickness of the sprayed film is specified to be 50 μm or more, preferably set to a range of 100 to 500 μm, more preferably set to within a range of 200 to 300 μm.

Furthermore, in the above vacuum depositing apparatus part, it is preferable that a surface of the sprayed film is subjected to a plastic work. Generally, the surface roughness of the sprayed film can be controlled to be within a predetermined range by only a spray treatment for the film. However, in this case, fine irregularities and void portions are liable to be formed, so that abnormally grown portions are also liable to be formed at the irregularities and void portions as starting points. These abnormally grown portions are easily dropped off from the surfaced of the sprayed film thereby to be a factor of generating the particles. Accordingly, it is necessary to eliminate defectives such as above irregularities and void portions by conducting the plastic work to the surface of the sprayed film.

Further, it is preferable that the plastic work is at least one of a ball shot treatment and a dry ice treatment. The ball shot treatment (ball blast treatment) is a method in which fine abrasive grains each having a round ball shape together with a high-pressured fluid are collided with a surface of a member to be treated (the sprayed film) thereby to conduct a surface treatment. According to the ball shot treatment, dimples can be formed without remaining any abrasive grains on the surface of the member to be treated and without imparting any damage (formation of fracture layer). A shape (diameter and depth) of these dimples can be adjusted by controlling treating conditions such as diameter of ball as abrasive grain, blast distance (spray distance) of the abrasive grain, blast pressure (spraying pressure), ball shot time, and so on.

The dry ice treatment is a method in which dry ice pellets are blasted to a surface to be treated thereby to clean the ball shot treated surface. According to this dry ice treatment, foreign substances remained after conducting the ball shot treatment to the surface of the member to be treated (sprayed film) can be removed in a short time by the action of sublimation energy of the dry ice, and the dimples formed by the ball shot treatment can be maintained to be clean.

In addition, since particles such as scattered particles that are easily peeled-off are remained to the surface of the sprayed film, in a case where the ball shot treatment is performed under this state, a film which is formed by crushing the scattered particles and is very easily peeled-off is existing on the ball shot treating surface. Therefore, when the dry ice treatment is conducted to the sprayed film at first, the scattered particles that are easily peeled-off are removed, so that there is no formation of an abnormally piled portion that is easily peeled-off.

In particular, when the above ball shot treatment is combined with the dry ice treatment, both an elongation of life span of the part and an effect of reducing the particles can be realized. Particularly, when the above ball shot treatment and the dry ice treatment are used in combination, even if fine irregular portions are caused and remained by one treatment, another treatment can remove the fine irregular portions, so that it becomes possible to eliminate the defected portions that are factors of generating the particles, and even a fine particle having a diameter of about 0.1 μm can be also reduced.

In contrast, in a conventional blast treatment, sharp abrasive grains each having a sharp edge portion are collided with the surface of a member to be treated, the abrasive grains are liable to bite into the member to be treated, so that a crushed layer (fracture layer) is liable to be formed to the surface of the member to be treated, and the member is easily harmed and damaged. Therefore, although the surface of the sprayed film could be formed to be coarse, so many damages were remained, so that it was impossible to completely eliminate the generation of the fine particles.

Furthermore, in the above vacuum depositing apparatus part, it is preferable that a duration time of the vacuum depositing apparatus part is 1500 kWh or more in terms of integral power consumption when the vacuum depositing apparatus in which a material component is vaporized by colliding ion, which is electrically accelerated, with a thin-film forming material is used for forming the thin film by depositing the vaporized component on the substrate, and the duration time of the vacuum depositing apparatus part is defined as an integral power consumption required for a sputtering period capable of continuously performing a film forming operation until number of particles mixed into the thin film deposited onto the vacuum depositing apparatus part exceeds 20.

In a case where the above duration time expressed by the integral power consumption required for sputtering operation using the vacuum depositing apparatus part is 1500 kWh or more, the time span until the film-peeling-off occurs is prolonged, and a time period capable of continuously performing a film forming operation can be extended to a long time period, so that a labor cost required for cleaning or replacing the part can be greatly reduced. As a result, the operation control of the depositing apparatus becomes extremely easy, the productivity of the film products can be increased, and it becomes also possible to reduce the depositing cost.

The vacuum depositing apparatus according to the present invention is characterized by comprising either one of the above vacuum depositing apparatus parts as a constituent member. In a case where the thin-film forming material is heated and vaporized in this vacuum depositing apparatus by using a resistance heating method, a high frequency heating method or an electron beam heating method, an operation pressure (vacuum degree) in the vacuum chamber is controlled to be 1×10⁻² Pa or less.

Further, in a case where the thin-film forming material is heated and vaporized by using a DC sputtering method, a high frequency sputtering method or a magnetron sputtering method or the like, the operation pressure (vacuum degree) in the vacuum chamber is set to be about 1×10⁻² Pa to 1 Pa.

Furthermore, in a case where a Ti target is sputtered in nitrogen atmosphere to form the TIN film, a vacuum chamber of the sputtering apparatus is vacuum-exhausted to attain a vacuum degree of 1×10⁻⁶ Torr or less. Thereafter, a mixed gas (Ar50%+N₂50%) is introduced into the vacuum chamber so as to attain a vacuum degree of about 5×10⁻³ Torr. (1 Torr=1.33×10² Pa)

When the vacuum depositing apparatus according to the present invention is a sputtering apparatus, the effect of reducing particles and the elongation of the duration time of the part become particularly remarkable.

In contrast to the present invention, as disclosed in the Patent Document 2, the conventional vacuum depositing apparatus part has adopted a countermeasure such that a surface of a sprayed film formed on the surface of the part is made to be a concavo-concave state thereby to increase a surface area and an anchor effect of the concavo-concave surface is used for preventing the peel-off of the piled film deposited on the vacuum depositing apparatus part. This countermeasure has been conventionally considered to be reasonable indeed. From these reasons, there has been generally used a sprayed film of which surface roughness Ra is controlled to be 30 μm or more.

However, according to the technical knowledge of the inventors of this invention, in a case where the surface roughness is increased, the piled film is piled along the shape of the surfaced of the sprayed film, so that the film projection is formed due to the concavo-concave surface of the piled film, and the unstable particles are piled to the film projection whereby this state has been a factor of inducing the generation of the particles contrary to popular belief. Therefore, in order to reduce the particles, it is necessary to make the surface of the sprayed film as smooth as possible, and the control of the surface roughness and shape of the sprayed film is an important factor. These technical findings have been obtained from various investigation results.

The above sprayed film is formed through the method in which a raw material such as powder or wire is molten using a heat source such as electricity and combustion gas and so on, and the molten particles are blasted to the part body utilizing a dispersion gas such as Ar gas or compressed air or the like. Therefore, when the molten particles are deposited to the part body, the surface roughness of the sprayed film varies in accordance with the size of the molten particles. Accordingly, in a case where the spraying operation is performed by an arc-spraying method using a wire raw material or a flame spraying method, since a wire diameter is constant, even if the spraying conditions are suitably selected, it was difficult to stably form a sprayed film having a surface roughness Ra of 10 μm or less.

On the other hand, in case of the plasma spraying method using powders as raw material or the flame spraying method, when the sprayed film is coated to have a thickness of about 200 to 300 μm, a surface roughness of about 6 μm can be obtained by controlling the size of the material powder. However, it was extremely difficult to stably control such the surface roughness of the sprayed film in accordance with the shape of the part.

Further, in a case where a sprayed film structure in which planiform (compressed) particles are deposited is formed, when the molten particles are deposited, particles collided the part are scattered and adhered to the sprayed film. Therefore, there is formed a surface structure in which the scattered particles are unstably piled up on the planiform particles. When the sprayed film having the above surface structure is used to the vacuum deposition apparatus as it is, an adhered film is piled in accordance with a shape of the sprayed film, so that there may be a state where the particles are liable to generate from the surface of the adhered film. Accordingly, it was necessary to frequently remove the scattered particles adhered to the surface of the sprayed film.

In the present invention, the inventors had obtained technical findings such that the effect of lowering the particle generation and the effect of elongating a duration time of the part can be obtained when the surface roughness Ra of the sprayed film is controlled to be 10 μm or less, or when the scattered particles adhered to the sprayed film are removed. Therefore, it was confirmed that it is necessary to remove the scattered particles after the spraying operation as a surface treatment which causes no further contamination, or that it is necessary to conduct a post-treatment for making the surface of the sprayed film flat and smooth by adopting a special method. Accordingly, when the above post-treatment is added to the spraying operation, it was confirmed that the generation of the particles can be greatly decreased and the duration time of the part can be also greatly prolonged.

As described above, when controlling the surface condition of the part after completion of the spraying operation, it becomes possible to stably pile the adhered substances on the sprayed film, so that the particle generation and film peeling-off can be stably and effectively suppressed.

Further, since the surface of the sprayed film is in a smooth condition, the adhered film piled on the sprayed film is also in a smooth condition in accordance with the smooth condition of the sprayed film, so that it becomes possible to eliminate the generation of the abnormal projection which causes the particles formed to the sprayed film which is formed by depositing the molten material. Accordingly, the effect of greatly reducing the amount of particle generation can be obtained.

Therefore, the generation of the particles induced by the adhered substance piled on the vacuum deposition apparatus part and the peeling-off of the piled film can be effectively suppressed. In addition, the frequency of cleaning the vacuum deposition apparatus and a number of times for replacing the part can be greatly decreased. This decreasing the amount of the particle generation greatly contribute to improve a production yield of the various thin films formed by the vacuum deposition apparatus and the element or part using the thin film. The decrease of the frequency of cleaning the vacuum deposition apparatus and a number of replacing the part greatly contribute to improve the productivity and a cost of forming the film, thus exhibiting an excellent effect.

As described above, according to the vacuum depositing apparatus part of the present invention, it is possible to stably and effectively prevent to peel-off the film forming material adhered to the part during the depositing step. In addition, it becomes also possible to increase a stability of the film per se for preventing the peeling-off. Accordingly, the frequency of cleaning the vacuum deposition apparatus and the number of times for replacing the part can be greatly decreased.

Further, according to the vacuum depositing apparatus of the present invention comprising the above vacuum depositing apparatus part, it becomes possible to prevent the mixing of the particles into the film, the particles being factor of generating defects of wiring films or elements. In addition, it becomes also possible to improve the productivity of the film and to decrease the cost of forming the film.

### BRIEF DESCRIPTION OF THE DRAWINGS

FIG. 1 is a partial cross sectional view showing a structure of a vacuum depositing apparatus part according to the present invention.

FIG. 2 is a partial cross sectional view showing an operation of adjusting a surface property of a sprayed film by conducting a ball shot treatment for the vacuum depositing apparatus part according to the present invention

FIG. 3 is a cross sectional view schematically showing a structure of a vacuum depositing apparatus using the vacuum depositing apparatus part according to the present invention.

### BEST MODE FOR CARRYING OUT THE INVENTION

The mode for carrying out the present invention will be explained hereunder.

In order to realize the reduction of the particle generation in the vacuum depositing apparatus and the reduction of times of replacing the part, it is necessary to appropriately control the surface roughness of the sprayed film in accordance with a kind of film to be formed on the surface of the part body. In case of the Ti/TiN film to be used for a diffusion barrier for an Al wiring film, for the purpose of exhibiting the above effect, the surface roughness is required to be set to 10 μm or less in terms of arithmetical average surface roughness Ra, more preferably to set to 8 μm or less.

As a concrete method of obtaining such the sprayed film (coated film), a plasma spraying method or an arc spraying method can be appropriately selected and used. As a spraying material, a powder or a wire is used. In order to control the surface roughness Ra to be 10 μm or less, it is necessary to use the powder having a specified grain size or use the wire having a specified diameter.

With respect to thus obtained sprayed film, a ball shot treatment is conducted thereby to plastic-deform the surface of the sprayed film, so that the surface roughness of the sprayed film is finally controlled to be 10 μm or less. At a time of this ball shot treatment, when a diameter, material of the ball, a spraying pressure, shot conditions such as shot distance, shot angle and so on are controlled, the surface roughness of the sprayed film and the surface configuration or the like can be controlled and adjusted.

The above spraying method is a method in which a supplied powder or wire is molten by a heat source of plasma discharge or arc discharge, the molten material is sprayed to the part body thereby to form a sprayed film having a film structure in which planiform (planular) grains are piled. However, there can be also used a flame spraying method in which the supplied powder or the wire is molten by a heat source of combustion gas, and the powder or wire in molten state is blasted to the part body.

On the other hand, when the plasma spraying condition for the supplied powder is controlled, there can be obtained a porous sprayed film in which the supplied powder exists as a granular- or ellipsoidal-shaped grain. When the sprayed film having the above structure is subjected to the ball shot treatment thereby to conduct a plastic work, a stress mitigating function can be further increased. Therefore, the following novel technical findings had been obtained. Namely, it becomes possible to prolong the duration time of the part, and there can be obtained a sprayed film capable of reducing the particles.

Therefore, in order to decrease the dust (particles) in the vacuum depositing apparatus and decrease the part replacing times, it is necessary to appropriately control the surface roughness of the sprayed film in accordance with a kind of a film to be formed. It is preferable that the sprayed film has a plurality of dimples formed to a surface of the sprayed film, and the dimples have an average depth of 5 to 30 μm.

In case of the Ti/TiN film to be used for a diffusion barrier for an Al wiring film, for the purpose of exhibiting the above effect, it is preferable that an average depth of dimples is controlled to within a range of 5 to 12 μm.

Further, in case of a high temperature atmosphere where a temperature of the film forming operation attains to about 500° C., it is preferable that the average depth of the dimples is controlled to within a range of 12 to 18 μm. Further, the sprayed film has a relative density of 75 to 99% due to pores existing in the sprayed film. On the other hand, an average grain size of non-planular grains constituting the sprayed film is set to a range of 5 to 150 μm, more preferably to a range of 5 to 55 μm. When the relative density and the average grain size of the sprayed film are set to the above ranges, there can be exhibited effects of both decreasing the dust (particles) due to the control of the surface roughness of the sprayed film and elongation of the duration time of the sprayed film due to the stress mitigating capability.

When the above relative density is greater than 99% or the average grain size is less than 5 μm and a stress is applied to the sprayed film, a crack is liable to occur among the grains, and the stress mitigating capability is lowered whereby the sprayed film is peeled off. Further, when the relative density is less than 75% or the average grain size exceeds 150 μm, irregularities of the surface of the sprayed film becomes notable, there is generated a large amount of the dust (particles) that are generated from the projection formed on a surface of the adhered substance piled in accordance with the surface condition of the sprayed film. Therefore, the more preferable range of the above relative density is 97% to 99%.

On the other hand, in case of TiW film to be used as a gate electrode film, an internal stress of the film is large. Therefore, it is preferable that the average depth of the dimples for the sprayed film is controlled to within a range from 23 μm to 30 μm in order to prolong the duration time of the part. Accordingly, when the relative density of the sprayed film is set to 75% to 99% and the average diameter of the grains is set to a range from 5 μm to 150 μm, more preferably to a range from 45 μm to 150 μm, the above effect of improving the duration time of the part can be exhibited.

When the above relative density exceeds 99% or the average grain size is less than 5 μm, a crack is liable to occur among the grains due to a large stress of the piled film adhered to the sprayed film, and the stress mitigating capability is lowered whereby the sprayed film is peeled off. Further, when the relative density is less than 75% or the average grain size exceeds 150 μm, irregularities of the surface of the sprayed film becomes notable, so that there is generated a large amount of the dust (particles) that are generated from the projection formed on a surface of the adhered substance piled in accordance with the surface condition of the sprayed film. Therefore, the more preferable range of the above relative density is 97% to 99%.

As described above, in order to realize both effect of decreasing the dust (particles) and effect of decreasing the part replacing times (i.e. elongation of the duration time of the part) in the vacuum deposition apparatus, it is necessary to increase the stress mitigating capability of the sprayed film by controlling the relative density of the sprayed film in accordance with kinds of the films to be formed and by controlling the size of the grains contained in the sprayed film. Due to the control of the relative density and the size of the grains, the surface roughness and the surface condition are optimized, so that it can be realized a surface condition capable of hardly generating the dust (particles), whereby there can be obtained a sprayed film capable of exhibiting the above both effects of decreasing the particle and the part-replacing times.

The above grain contained in the above sprayed film structure has a shape different from the planular shape. Example of the shapes of the grain may include a grain having a spherical-shaped cross section or an ellipsoidal cross section. It is preferable that this grain of the sprayed film has a planular ratio (Y/X) of 0.25 to 1.5 when a transversal length of each grains with respect to a thickness direction of the sprayed film is assumed to be X while a longitudinal length of each grains with respect to a thickness direction of the sprayed film is assumed to be Y.

This limitation relies on a reason to be explained hereunder. Namely, when the planular ratio (Y/X) is less than 0.25, the grain would have a shape close to the planular shape, so that the crack is liable to occur when a stress is applied to the sprayed film.

On the other hand, when the planular ratio (Y/X) exceeds 1.5, the grain would have a shape close to a columnar crystal shape. In this case, there is advanced a reaction in which small size grains are molten and adhered to a surface of large size grains, so that the crack is liable to occur when the stress is applied to the sprayed film. A more preferable range of the planular ratio (Y/X) is 0.4 to 1.2.

A number of the above grains each having a shape different from the planular shape denotes a number of the grains existing in a unit cross sectional area of 0.0567 mm² when the cross sectional area is obtained by cutting the sprayed film in a thickness direction.

The number of the above grains varies in accordance with a setting of the surface roughness for the spayed film. In a case where the average depth of the dimples is 5 to 10 μm, the number of the grains should preferably set to be 50 to 120. Further, in a case where the average depth of the dimples is 10 to 20 μm, the number should preferably be 20 to 50. Furthermore, in a case where the average depth of the dimples is 20 to 30 μm, the number should preferably be 2 to 20. Due to the controlling of the number of the existing grains, it becomes possible to sufficiently suppress the generation of the cracks in the sprayed film due to a high stress of the piled film to be adhered to the sprayed film.

In this connection, when the number of the existing grains is out of the above ranges, an existing ratio of small-sized grains is large even if the average grain size satisfies the range of 5 μm to 55 μm, so that there may be a fear such that a bonding strength between the sprayed film and the base member becomes insufficient. Therefore, the number of the existing grains is preferably set to 85±20 in a case where the average depth of the dimples is 5 to 10 μm, the number is preferably set to 35±10 in a case where the average depth of the dimples is 10 to 20 μm, and the number is preferably set to 11±5 in a case where the average depth of the dimples is 20 to 30 μm.

Further, it is also preferable that a planular grain exists in the above-sprayed film. This planular grain is obtained from a result of the spraying material powder being molten. A surface of a grain having a different shape from that of the planular grain can be covered by the planular grain, so that a drop-off of the particle from the sprayed film can be prevented.

As a concrete method of forming such sprayed film, a plasma spraying method, an ultra high-speed flame spraying method or the like can be appropriately selected and used in accordance with a kind of constituting material or shape of the part body, environmental condition under which the part is used, or a spraying material. As a spraying material, a powder is used for controlling the density of the sprayed film and a size of the grains contained in the sprayed film. Taking the density, size of the grains, the control of sprayed surface roughness into consideration, an appropriate grain size range of the powder to be supplied is selected and the powder is used, so that aimed density, grain size and surface roughness can be obtained.

When the spraying conditions such as current, voltage, gas flow rate, pressure, spraying distance, nozzle size, amount of material to be supplied are controlled, the relative density of the sprayed film, the size or distribution state of the grains, surface roughness and film thickness can be controlled.

The above spraying method is a method in which the supplied powder is molten by a heat source generally using a plasma discharge or a combustion gas, and the molten material is piled on a part body as planular grains thereby to obtain a sprayed film having a film structure. However, when the conditions such as current, voltage, kind of plasma gas, kind of combustion gas, amount of the combustion gas and so on are appropriately controlled, it becomes possible to blast the supplied powder without completely melting the supplied powder, so that there can be provided a sprayed film in which granular grains or ellipsoidal grains exist.

At this time, if only the surface portion of the powder is in a molten state, such molten state strengthens a diffusion bonding property, so that it is important to accurately control the above spraying conditions,

For example, at the time of a plasma spraying operation, when the current and the voltage are set to be lowest limits capable of generating the plasma thereby to prevent the temperature of the plasma from increasing and argon gas is selected as the plasma gas thereby to prevent the temperature of the plasma from increasing, it becomes possible to melt only the powder surface.

On the other hand, in case of the ultra high-speed flame spraying method, a supplying amount of the combustion gas is decreased thereby to lower the combustion temperature; it becomes possible to melt only the powder surface.

In case of the plasma spraying method, in order to firmly adhere the powder of which only surface is in molten state to a part body without causing a piling of the powder due to the partial melting, it is preferable that the gas pressure and gas flow rate to be blasted are set to be high, and it is required that the pressure and the flow rate are set to a highest limit of a spraying apparatus used. Since an argon gas is selected as the plasma gas, when the gas pressure and the flow rate of the gas to be blasted are set to be high, argon gas atmospheric region can be extended, so that it becomes possible to suppress the nitriding and oxidizing of the sprayed film.

On the other hand, in case of the ultra high-speed flame spraying method, an amount of oxygen for accelerating the combustion is set to be relatively lower than an amount of acetylene thereby to lower the combustion temperature and the grains are accelerated to a high speed by the action of the argon flow rate, so that it becomes possible to adhere the grains to a part body without causing the melting of the grains.

Further, in case of the plasma spraying method, examples of preferable conditions of the gas pressure and the gas flow rate to be blasted are as follows. Namely, the average grain size of the powder to be blasted is 20 to 100 μm, the current applied to a plasma device is 300 to 500 A, the voltage is 30 to 45 V, Ar gas flow rate is 70 little/min. or more, and the gas pressure is 100 PSI (pound per square inch) or more.

An upper limit of the Ar gas flow rate and the gas pressure are not particularly limited. However, when the Ar gas flow rate and the gas pressure are excessively high, the planular shape of the grain is liable to deviate from a preferable range. Therefore, the upper limit of the Ar gas flow rate is preferably set to 280 little/min. or less, and the gas pressure is preferably set to 280 PSI or less.

Furthermore, the relative density of the sprayed film is obtained through the following method. At first, the sprayed film is cut in a thickness direction to obtain a cross sectional structure, and this cross sectional structure is observed by means of an optical microscope of 500 magnifications. Then, a void area existing in an observation field of 210 μm (vertical length)×270 μm (horizontal length) is measured. The measured data is converted into a relative density in each of the observation fields on the basis of an equation (1), and the relative density of the sprayed film is calculated by averaging the respective converted values of 10 observation fields.

Relative Density(%)=[(S₁−S₂)/S₁]×100 (1)

In the above equation (1), S₁ denotes an observation field area (μm²) of 210 μm (vertical length)×270 μm (horizontal length), while S₂ denotes a total area (μm²) of voids existing in the observation field of 210 μm (vertical length)×270 μm (horizontal length).

Further, the planular ratio, the average grain size and the number of grains existing in the film structure shall be obtained through the following method. That is, the sprayed film is cut in a thickness direction to obtain a cross sectional structure, and this cross sectional structure is observed by means of an optical microscope of 500 magnifications. Then, with respect to each of the grains existing in the observation field of 210 μm (vertical length)×270 μm (horizontal length), a length (Y) of the grain in a longitudinal direction parallel with the thickness direction of the sprayed film and a length (X) of the grain in a transversal direction normal to the thickness direction of the sprayed film are measured thereby to calculate the planular ratio (Y/X).

In this connection, with respect to a grain of which part is appeared within the observation field, such grain shall be excluded from measuring object, and only the grains capable of being confirmed an entire image shall be adopted as the measuring object. This measuring operation shall be repeated to each of 10 observation fields. A number of grains each having the planular ratio (Y/X) of 0.25 to 1.5 shall be calculated with respect to each of the afore-mentioned 10 observation fields (each observation field area: 0.0567 mm²). The observation field area: 0.0567 mm² is calculated from an equation of 210 μm (vertical length)×270 μm (horizontal length).

When a part formed with thus prepared sprayed film is subjected to an annealing treatment for the purpose of softening and degassing the sprayed film, it becomes possible to further increase the stress mitigating capability.

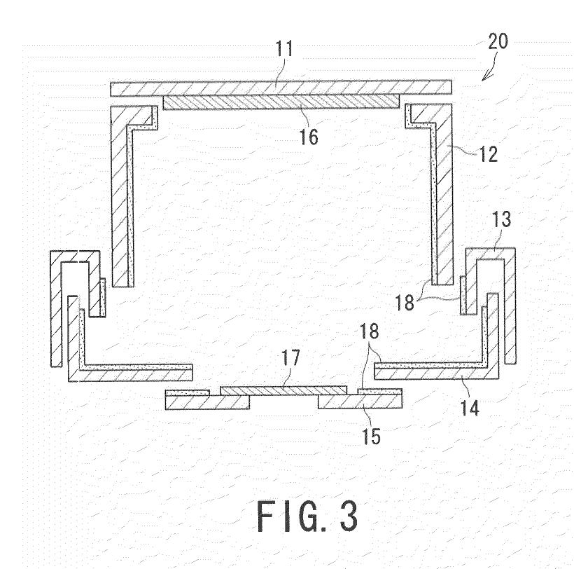

Next, an embodiment of the vacuum depositing apparatus according to the present invention will be explained with reference to the accompanying drawings. FIG. 3 is a view schematically showing a structure of a substantial part of one embodiment of the vacuum depositing apparatus in which the vacuum depositing apparatus according to the present invention is applied to a sputtering apparatus.

This sputtering apparatus comprises: a vacuum chamber (not shown); a backing plate 20 as a film forming source holding portion provided in the vacuum chamber; and a sputtering target 21 as film forming source fixed to the backing plate 20. An earth shield 22 is disposed to a lower portion of an outer peripheral portion of the sputtering target 21 in the vacuum chamber. A substrate 23 to be formed with the film is held by the platen ring 24 as a substrate-holding portion, and the substrate 23 in the state is arranged in the vacuum chamber so as to oppose to the sputtering target 21. An upper adhesion preventing plate 25 and a lower adhesion preventing plate 26 as the adhesion preventing plates are provided to a portion between the backing plate 20 and the platen ring 24 in the vacuum chamber. Each of the film material adhesion surfaces of the earth shield 22, the platen ring 24, the upper and lower adhesion preventing plates is formed with a sprayed film 27 used in the present invention. Further, the vacuum chamber is connected with a gas supplying system (not shown) for introducing a sputtering gas therein, and connected with a discharging system (not shown) for discharging air in the vacuum chamber to attain a predetermined vacuum state of the vacuum chamber.

In the above sputtering apparatus, during the depositing operation, a sputtered film forming material (material constituting the target) is adhered to each of the surfaces of the sprayed films 27 of not only the substrate to be formed with the film but also the earth shield 22, the platen ring 24, the upper adhesion preventing plate 25 and the lower adhesion preventing plate 26. However, a dropping-off of the particle from an adhered film and a peeling-off of the adhered film can be prevented by the sprayed film.

By the way, the above embodiment has been explained by taking an example in which the vacuum depositing apparatus of the present invention is applied to the sputtering apparatus. However, as the other applications, the vacuum depositing apparatus of the present invention can be also applied to the other vacuum depositing apparatus (including an ion plating device or a laser ablation device) or CVD device. Even in the above cases, the same effects as in the above sputtering apparatus can be also obtained.

In thus prepared sprayed film formed by molten material or the sprayed film formed by non-molten material, adhesion substances such as scattered particles and non-molten particles that are liable to drop off would adhere and remained to the surface of the sprayed film, so that it is important to remove the adhesion substances by utilizing a dry ice cleaning treatment.

In this regard, even if the dry ice used as abrasive grains is collided and remained at the surface of the sprayed film, the dry ice is vaporized in a short time, so that the dry ice per se would not contaminate the surface of the sprayed film. Therefore, the dry ice cleaning treatment is effective as a pre-treatment for controlling the surface shape of the sprayed film.

In the dry ice cleaning treatment, a pellet-shaped dry ice grains having a diameter of several mm can be directly blasted to the surface of the sprayed film. Even in a case where a dry ice block is pulverized to prepare fine grains having a diameter of 1 mm or less and blasted the fine grains to the part, it becomes possible to remove the scattered particles. At this time, when a gas pressure to be blasted is 2 Kg/cm² or more, the effect of removing the scattered particles can be exhibited. In contrast, when the gas pressure is less than 2 Kg/cm², it becomes impossible to completely remove the scattered particles.

When this dry ice cleaning treatment is not performed in advance, there is tendency that the scattered particles and the non-molten particles having a poor close-contacting property with respect to the sprayed film are plastically deformed to a planular shape by the ball shot operation, the deformed particles are piled on the sprayed film, so that the sputtered and piled films are liable to peel-off. As a result, such tendency becomes an obstruction for life-up measure of the parts, so that it is preferably adequate to perform the dry ice cleaning treatment in advance prior to a plastic work.

As a hard ball (rigid ball) used in the ball shot treatment, a spherical ball composed of an ordinal steel, stainless steel, ceramics material and so on is used. In this case, the spherical ball can be repeatedly used without causing a breakage of the spherical ball per se even if a strong impact force due to the blasting is applied to the spherical ball. Further, as a diameter of the spherical ball, 2 mm or less is preferable. In a case where the diameter of the spherical ball exceeds 2 mm and the spherical ball is coarse, a collision force of the spherical ball would not reach to a concave portion formed on the surface of the sprayed film. As a result, there is generated a portion where a sprayed configuration is remained as it is, so that the sprayed surface is not formed to have an entirely uniform shape

As a blasting pressure in the above ball shot treatment, a pressure can be adopted as far as the pressure allows the spherical ball to be blasted with a uniform kinetic momentum. Concretely, the pressure is preferably set to 5 Kg/cm² or less. However, when the blasting pressure is set so as to exceed 5 Kg/cm², the sprayed film surface is extremely and plastically deformed, so that it becomes difficult to obtain a desired surface roughness.

On the other hand, when the above blasting pressure is set to be excessively low, the spherical ball cannot be stably blasted, so that the sprayed film surface is not formed to be completely smooth. As a result, there is formed a non-uniform feature where the sprayed configuration is remained as it is, so that a productivity of the sprayed film is disadvantageously lowered.

Furthermore, after completion of the ball shot treatment, when the dry ice shot treatment is performed in combination with the ball shot treatment, the adhered substances remained on the smooth sprayed film are removed, so that there can be exhibited an effect of forming a surface having no foreign material, and this effect results into a further reduction of the particles, thus being effective countermeasure.

When a part formed with thus prepared sprayed film is subjected to an annealing treatment for the purpose of softening and degassing the sprayed film, it becomes possible to further increase the stress mitigating capability.

### Embodiment

Next, a concrete embodiment of the vacuum depositing apparatus according to the present invention will be explained with reference to the accompanying drawings.

FIG. 3 is a cross sectional view schematically showing a structure of a sputtering apparatus which is one embodiment of the vacuum depositing apparatus according to the present invention. This sputtering apparatus 20 is configured by comprising: a sputtering target fixing plate 11 for fixing and holding a sputtering target 16; and a vacuum chamber comprising an earth shield 12, an upper adhesion preventing plate 13, a lower adhesion preventing plate 14 and a platen ring 15 wherein the sputtering target 16 is provided so as to oppose to a material (wafer) 17 to be formed with a film.

Each of the earth shield 12, the upper adhesion preventing plate 13, the lower adhesion preventing plate 14 and the platen ring 15 that are all vacuum depositing apparatus parts is formed with a film 18 prepared through film forming methods such as the spraying method and so on.

By the way, the present embodiment will be explained by using the sputtering apparatus as a vacuum depositing apparatus. However, the vacuum depositing apparatus part and the vacuum depositing apparatus of the present invention includes vacuum deposition apparatuses (including an ion-plating apparatus and a laser ablation apparatus or the like) and CVD devices or the like other than the sputtering apparatus. In also the other apparatuses, the same effects as those in the sputtering apparatus can be obtained.

### Examples 1-7

An earth shield 12, an upper adhesion preventing plate 13, a lower adhesion preventing plate 14 and a platen ring 15 that are all constituting parts of the sputtering apparatus 20 shown in FIG. 3 were prepared as the following manner. Namely, with respect to above the earth shield 12, the upper adhesion preventing plate 13, the lower adhesion preventing plate 14 and the platen ring 15 of which part bodies (base members) are all composed of stainless steel (SUS304), a surface preparation was conducted to surfaces of the part bodies by using a blast treatment. Thereafter, using spraying materials shown in Table 1, sprayed films each having a thickness shown in Table 1 were formed through a plasma spraying method.

In this plasma spraying method, an Ar+H₂ flame was used, and 90 mass % Cu—Al powder material having a grain size of 45 μm or less, Cu powder material and Al powder material were used thereby to form the respective sprayed films.

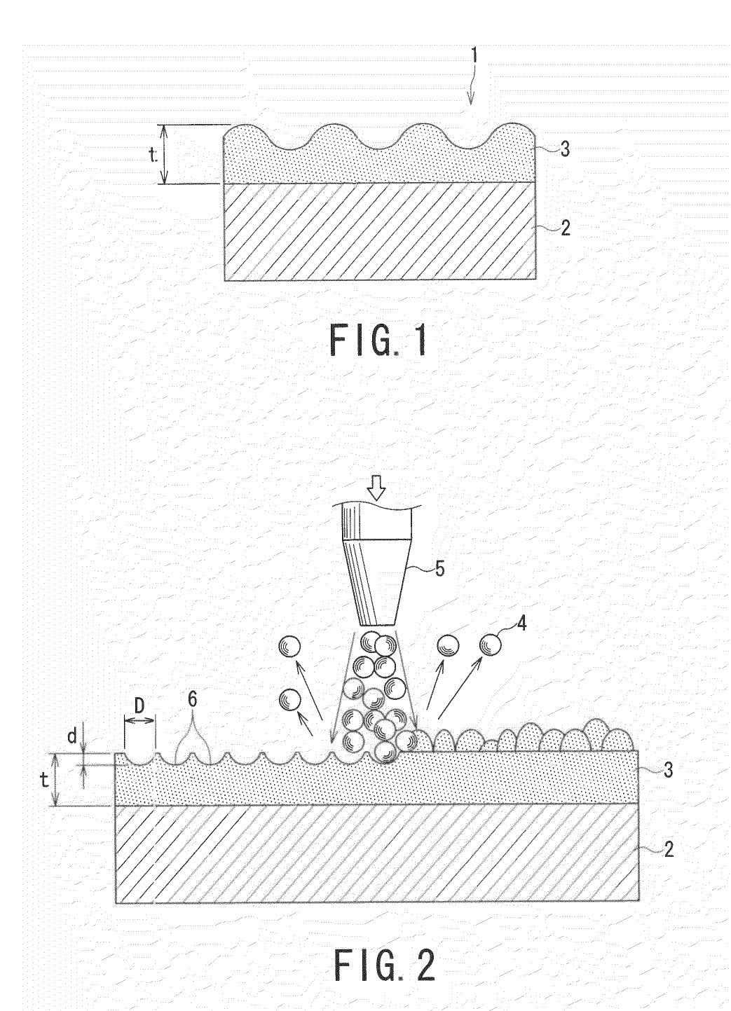

Thus prepared each of the vacuum depositing apparatus parts 1 has a structure in which the sprayed film 3 having a predetermined thickness t is integrally formed to a surface of the part body 2 as shown in FIG. 1,

With respect to the parts formed with the sprayed films 3 as described above, as shown in table 1, a post treatment was performed by conducting the ball shot treatment once, or by conducting the post treatment twice or more by conducting the ball shot treatment in combination with the dry ice treatment.

In this regard, as shown in FIG. 2, the above ball shot treatment was performed in such a manner that stainless steel balls 4 each having a diameter of 0.8 mm were ejected from an ejection nozzle 5 to a surface of the sprayed film 3 formed onto each surface of the part bodies 2 under an ejecting pressure of 5 Kg/cm².

On the other hand, the above dry ice treatment was performed in such a manner that dry ice grains each having a diameter of 0.3 mm were ejected from the ejection nozzle 5 to the surface of the sprayed film 3 under the same ejecting pressure of 5 Kg/cm².

When the above ball shot treatment is performed, a surface portion of the sprayed film 3 is subjected to a plastic work and deformed, so that a number of dimples 6 each having a curved surface of which shape corresponds to an outer surface shape of the ball as shown in FIG. 2. A diameter D and a depth d of this dimple 6 can be controlled by adjusting shot conditions such as ball diameter and the ejecting pressure.

On the other hand, when the above dry ice shot treatment is performed, the adhered substances and the projected portions remained on the sprayed film surface before the ball shot treatment can be easily removed thereby to perform an almost complete cleaning.

Next, with respect to each of the parts subjected to the post treatments such as the ball shot treatment and the dry ice shot treatment as described above, a heat treatment was performed under a vacuum atmosphere of 3×10⁻² Pa or less at a temperature of 350 ° C. for 3 hours, so that an annealing effect and degassing effect were obtained, thereby to prepare vacuum depositing apparatus parts 1 for the respective Examples.

Further, there were used the earth shield 12, the upper adhesion preventing plate 13, the lower adhesion preventing plate 14 and the platen ring 15 as the vacuum depositing apparatus parts 1 for the respective Examples, so that the vacuum depositing apparatus 20 for the respective Examples 1 to 7 were assembled as shown in FIG. 3.

### Comparative Examples 1-2

As Comparative Examples for comparing with the present invention, following parts and apparatuses were prepared. Namely, a plasma spraying operation was performed under the same conditions as in Examples to a surface of each part bodies composed of the same materials as those of Examples, thereby to form the respective sprayed films each having a thickness shown in Table 1. With respect to thus obtained sprayed films composed of 90 mass % Cu—Al, the post treatment was not performed but a heat treatment as annealing treatment and a degassing treatment was performed under a vacuum atmosphere of 3×10⁻² Pa or less at a temperature of 350° C. for 3 hours, so that the vacuum depositing apparatus parts 1 for the respective Comparative Examples 1 to 2 were prepared. Further, by using these vacuum depositing apparatus parts 1, the vacuum depositing apparatus of the respective Comparative Examples 1 to 2 were assembled as shown in FIG. 3.

With respect to each of thus assembled the vacuum depositing apparatuses of Examples and Comparative Examples, a Ti sputtering target 16 having a diameter of 127 mm was attached. Then, a magnetron sputtering operation was performed under the following conditions, thereby to form the respective laminated thin films of Ti/TiN onto an 8-inch wafer.

Sputtering Pressure: 3×10⁻⁵ Pa

Ar Flow Rate: 10 sccm (cm³/s)

N₂ Flow Rate: 30 sccm

Then, a number of dust (particles) each having a diameter of 0.1 μm or more that were mixed into the surface of the 8-inch wafer was measured by means of a particle counter (WM-3). In addition, an integrated power consumption value (kwh) required for the sputtering operation until the number of the mixed particles exceeds 20 pieces was measured, and the measured value was confirmed as a duration time of the respective apparatus constituting parts. These measuring results are shown in Table 1 hereunder.

TABLE 1

| | | | Thickness of | | Surface | Shape of Dimple (μm) | Number | Duration |
|---|---|---|---|---|---|---|---|---|
| | Film | Spraying | Sprayed | | Roughness | Average Diameter × | of Dust | Life |
| Sample No. | Material | Material | Film (μm) | Post Treatment | Ra (μm) | Average Dept [symbol] | (piece) | (kwh) |
| Example 1 | Ti/TiN | 90%Cu—Al | 200 | Ball | 5.5 | 110 × 10 | 5 | 1570 |
| Example 2 | Ti/TiN | 90%Cu—Al | 300 | Ball | 5.7 | 154 × 15 | 6 | 1580 |
| Example 3 | Ti/TiN | 90%Cu—Al | 300 | Dry Ice + Ball | 5.9 | 185 × 19 | 7 | 1600 |
| Example 4 | Ti/TiN | 90%Cu—Al | 250 | Ball + Dry Ice | 6.3 | 213 × 22 | 7 | 1650 |
| Example 5 | Ti/TiN | 90%Cu—Al | 300 | Dry Ice + Ball + Dry Ice | 6.6 | 256 × 25 | 9 | 1660 |
| Example 6 | Ti/TiN | Cu | 250 | Dry Ice + Ball + Dry Ice | 7.0 | 270 × 27 | 8 | 1610 |
| Example 7 | Ti/TiN | Al | 250 | Dry Ice + Ball + Dry Ice | 7.4 | 297 × 29 | 11 | 1620 |
| Comparative | Ti/TiN | 80%Cu—Al | 300 | None | 12.5 | — | 27 | 1490 |
| Example 1 | | | | | | | | |
| Comparative | Ti/TiN | 80%Cu—Al | 200 | None | 11.4 | — | 21 | 1470 |
| Example 2 | | | | | | | | |

[symbol]

indicates data missing or illegible when filed

As is clear from the results shown in Table 1, according to the magnetron sputtering apparatus as the vacuum deposition apparatus of the respective Examples in which the surface roughness Ra of the sprayed film formed to the respective constituting parts 1 was controlled to be 10 μm or less, it was confirmed that an amount of the particle generation could be greatly reduced in comparison with those of Comparative Examples in which the surface roughness Ra of the sprayed film exceed 10 μm. In addition, it was also confirmed that a duration time which indicates an operation time capable of continuously performing the sputtering operation until the peeling-off of the film occurred.

From these results, it was confirmed that the particle generation can be effectively and stably prevented, so that the duration life of the part and the apparatus per se could be extended.

In particular, when above two kinds of post treatments of the ball shot treatment and the dry ice shot treatment were sequentially performed, the adhered substances, that were remained on the surface of the sprayed film immediately after the sprayed film formation or immediately after the ball shot operation, could be effectively removed, so that the dropping-off of the adhered substances which had abnormally grown could be effectively prevented. Therefore, it was evidenced that the number of dusts such as particles and so on mixed onto the wafer could be further decreased. In this connection, when a density of each sprayed films of the vacuum depositing apparatus parts of Examples 1 to 7, the densities were all within a range of 91 to 99%.

### Examples 8-10

Next, in the sputtering apparatus as the vacuum depositing apparatus, the apparatus was operated under a condition that a sputtering power output was changed. Then, an influence of the sputtering power output on the amount of particle generation will be confirmed with reference to the following Examples and Comparative Examples.

The plasma spraying operation was performed under the same conditions as in Example 1 to a surface of each of part bodies 2 composed of the same material (SUS304) as that of Example 1, thereby to form the respective 90 mass % Cu—Al sprayed films each having a thickness of 300 μm. Further, with respect to thus obtained sprayed films composed of 90 mass % Cu—Al, the ball shot treatment was performed as in the same conditions as in Example 1, so that the vacuum depositing apparatus parts 1 for the respective Examples 8 to 10 having surface roughness Ra and a dimple shape shown in Table 3 were prepared. Further, by using these vacuum depositing apparatus parts 1 as the earth shield 12, the upper adhesion preventing plate 13, the lower adhesion preventing plate 14 and the platen ring 15, the vacuum depositing apparatus 20 of the respective Examples 8 to 10 were assembled as shown in FIG. 3.

### Comparative Examples 3-4

On the other hand, the plasma spraying operation was performed under the same conditions as in Example 1 to a surface of each of part bodies 2 composed of the same material (SUS304) as that of Example 1, thereby to form the respective 90 mass % Cu—Al sprayed films each having a thickness of 300 μm and a surface roughness Ra shown in Table 2, so that the vacuum depositing apparatus parts 1 for the respective Comparative Examples 3 to 4 were prepared. Further, by using these vacuum depositing apparatus parts, the vacuum depositing apparatus of the respective Comparative Examples 3 to 4 were assembled.

With respect to each of thus assembled the vacuum depositing apparatuses of Examples 8 to 10 and Comparative Examples 3 to 4, a Ti sputtering target 16 having a diameter of 127 mm was attached to a vacuum chamber of the vacuum depositing apparatus as the same manner as in Example 1. Then, a magnetron sputtering operation was performed under the following conditions, thereby to form the respective laminated thin films of Ti/TiN onto an 8-inch wafer.

Sputtering pressure: 3×10⁻⁵ Pa

Ar flow rate: 10 sccm (cm³/s)

N₂ flow rate: 30 sccm

Then, the sputtering operation was continuously performed until the integrated power assumption (kwh) for the sputtering power output attained to 1500 kwh. On the way to the final sputtering power output of 1500 kwh, whenever the integrated power assumption was attained to values shown in Table 2, an accumulated number of dust (particles) each having a diameter of 0.1 μm or more that were mixed into the surface of the 8-inch wafer was measured by means of the particle counter (WM-3). These measuring results (average values) are shown in Table 2 hereunder.

TABLE 2
Number of Generated Particles when Sputtering Power Output was Chang

| | Film Thickness 300 μm | | | | | | | |
|---|---|---|---|---|---|---|---|---|
| | Surface Roughness | Shape of Dimple (μm [symbol] | | | | | | |
| | of Sprayed Film | Average Diameter × | Sputtering Power Output (kWh) | | | | | |
| Sample No. | Ra (μm) | Average Depth | 100 | 300 | 500 | 800 | 1000 | 1500 |
| Example 8 | 4 | 107 × 7 | 4.1 | 3.5 | 5.3 | 4.7 | 6.9 | 7.7 |
| Example 9 | 6 | 118 × 12 | 3.8 | 5.8 | 4.6 | 5.9 | 7.1 | 6.7 |
| Example 10 | 8 | 288 × 27 | 6.2 | 7.4 | 6.6 | 7.2 | 8.5 | 9.7 |
| Comparative | 15 | — | 9.7 | 14.7 | 18.8 | 20.8 | 26.1 | 32.3 |
| Example 3 | | | | | | | | |
| Comparative | 30 | — | 10.5 | 15.5 | 19.8 | 25.5 | 30.3 | 34.2 |
| Example 4 | | | | | | | | |

[symbol]

indicates data missing or illegible when filed

As is clear from the results shown in Table 2, according to the sputtering apparatus of the respective Examples 8 to 10 in which the surface of the sprayed film constituting the parts was subjected to the plastic work (ball shot treatment) and the surface roughness Ra of the sprayed film formed to the respective constituting parts was controlled to be 10 μm or less, it was confirmed that the particle generation could be effectively suppressed for a long time period in comparison with those of Comparative Examples 3-4 in which the surface roughness Ra of the sprayed film exceed 10 μm.

On the other hand, according to the sputtering apparatus of the respective Comparative Examples 3 to 4, it was confirmed that there was a tendency that the amount of the generated particles was rapidly increased in accordance with elapse of the operation time for the apparatus. In this connection, when a relative density of each sprayed films of the vacuum depositing apparatus parts of Examples 8 to 10, the relative densities were all within a range of 91 to 99%.

### Examples 11-18

Next, in the sputtering apparatus as the vacuum depositing apparatus, the apparatus was operated under a condition that a sputtering power output was changed. Then, the influence of the sputtering power output on the amount of particle generation will be confirmed with reference to the following Examples and Comparative Examples.

The plasma spraying operation was performed under a spraying condition capable of forming a porous film containing non-molten grains to a surface of each of part bodies 2 composed of the same material (SUS304) as that of Example 1, thereby to form the respective Al sprayed films each having a thickness of 300 μm. Further, with respect to thus obtained sprayed films, the ball shot treatment was performed as in the same conditions as in Example 1, so that the vacuum depositing apparatus parts 1 for the respective Examples 11 to 16 having surface roughness Ra and a dimple shape shown in Table 3 were prepared.

Further, by using these vacuum depositing apparatus parts 1 as the earth shield 12, the upper adhesion preventing plate 13, the lower adhesion preventing plate 14 and the platen ring 15, the vacuum depositing apparatus 20 of the respective Examples 11 to 18 were assembled as shown in FIG. 3.

In this regard, in Examples 11 to 18, as spraying powder materials for the plasma spraying method, a powder having an average grain size of 26 μm (Example 11), 35 μm (Example 12), 65 μm (Example 14), 60 μm (Example 15), 70 μm (Example 16), 210 μm (Example 17) and 62 μm (Example 18) were used.

The plasma apparatus of Examples 11 to 12 performed the spraying operation under the conditions of electric current: 300 A, voltage: 35 V, Ar gas flow rate: 120 litter/min., pressure: 150 PSI.

The plasma apparatus of Examples 13 to 17 performed the spraying operation under the conditions of electric current: 400 A, voltage: 36 V, Ar gas flow rate: 100 litter/min., pressure: 160 PSI. The plasma apparatus of Example 18 performed the spraying operation under the conditions of Ar gas flow rate: 300 litter/min., pressure: 300 PSI.

### Comparative Examples 5-6

On the other hand, the same procedures as in Example 14 or Example 15 were repeated except that the ball shot treatment was not performed to a surface of the sprayed film, thereby to prepare the respective vacuum depositing apparatus parts of Comparative Examples 5-6. Further, by using these vacuum depositing apparatus parts as the earth shield 12, the upper adhesion preventing plate 13, the lower adhesion preventing plate 14 and the platen ring 15, the vacuum depositing apparatus of the respective Comparative Examples 5 to 6 were assembled as shown in FIG. 3.

With respect to each of thus assembled the vacuum depositing apparatuses of Examples 11 to 18 and Comparative Examples 5 to 6, a Ti sputtering target 16 was attached into a vacuum chamber of the vacuum depositing apparatus as the same manner as in Example 1. Then, a magnetron sputtering operation was performed under the following conditions, thereby to form the respective laminated thin films of WIN onto an 8-inch wafer.

Sputtering pressure: 3×10⁻⁵ Pa

Ar flow rate: 10 sccm (cm³/s)

N₂ flow rate: 30 sccm

Then, the sputtering operation was continuously performed until the integrated power assumption (kwh) for the sputtering power output attained to 1500 kwh. On the way to the final sputtering power output of 1500 kwh, whenever the integrated power assumption was attained to values shown in Table 3, an accumulated number of dust (particles) each having a diameter of 0.1 μm or more that were mixed into the surface of the 8-inch wafer was measured by means of the particle counter (WM-3). These measured results (average values) are shown in Table 3 hereunder.

TABLE 3

| | Film Thickness 300 μm | | | | | | | | | | | |
|---|---|---|---|---|---|---|---|---|---|---|---|---|
| | Sureface | | | | | | | | | | | |
| | Roughness of | Shape of Dimple (μm) | Film | Average | | Film | | | | | | |
| | Sprayed Film | Average Diameter × | Density | Grain Size | | Forming | Sputtering Power Output (kWh) | | | | | |
| Sample No. | Ra (μm) | Average depth | (%) | (μm) | Planular | Material | 100 | 300 | 500 | 800 | 1000 | 1500 |
| Example 11 | 5 | 112 × 8 | 89 | 32.4 | 0.45 | Ti/TiN | 2.5 | 4.3 | 2.5 | 3.9 | 3.1 | 4.7 |
| Example 12 | 6 | 121 × 12 | 84 | 45.2 | 0.63 | Ti/TiN | 2.6 | 4.7 | 4.1 | 3.5 | 4.4 | 4.9 |
| Example 13 | 8 | 271 × 26 | 81 | 65.5 | 0.91 | Ti/TiN | 3.1 | 3.8 | 4.6 | 5.4 | 3.9 | 5.6 |
| Example 14 | 9 | 285 × 29 | 77 | 71.3 | 1.13 | Ti/TiN | 4.6 | 3.2 | 3.7 | 5.3 | 4.9 | 5.8 |
| Example 15 | 8 | 279 × 27 | 80 | 68.7 | 0.88 | TiW | 17.5 | 24.2 | — | — | — | — |
| Example 16 | 9 | 295 × 29 | 76 | 75.4 | 1.06 | TiW | 12.7 | 17.5 | — | — | — | — |
| Example 17 | 8 | 265 × 21 | 76 | 230.1 | 1.03 | Ti/TiN | 8.2 | 11.7 | 15.9 | 15.1 | 13.4 | 21.2 |
| Example 18 | 7 | 260 × 19 | 74 | 67.5 | 0.15 | Ti/TiN | 7.4 | 10.1 | 15.5 | 14.3 | 13.6 | 20.4 |
| Comparative | 16 | None | 92 | — | — | Ti/TiN | 11.2 | 15.2 | 20.5 | 17.3 | 16.8 | 25.7 |
| Example 5 | | | | | | | | | | | | |
| Comparative | 33 | None | 93 | — | — | TiW | 35.1 | 45.9 | — | — | — | — |
| Example 6 | | | | | | | | | | | | |

As is clear from the results shown in Table 3, according to the sputtering apparatus of the respective Examples 11 to 14 in which the surface of the sprayed porous film constituting the parts was subjected to the plastic work (ball shot treatment) and the surface roughness Ra of the sprayed porous film formed to the respective constituting parts was controlled to be 10 μm or less, it was confirmed that the particle generation could be effectively suppressed for a long time period in comparison with those of Comparative Examples 5-6 in which the surface roughness Ra of the sprayed film exceed 10 μm.

On the other hand, according to the sputtering apparatus of the respective Comparative Examples 5 to 6, it was confirmed that there was a tendency that the amount of the generated particles was rapidly increased in accordance with elapse of the operation time for the apparatus.

In this connection, in case of Example 15, Example 16 and Comparative Example 6, when the sputtering power output attained to 300 kwh, the amount of generated particle become large, so that it was necessary to replace the vacuum depositing apparatus parts with new parts, whereby further operation for measuring performances could not be done. This reason was that a film stress of TiW film was larger than that of Ti/TiN film, so that the TiW film could not withstand a such continuous operation.

Further, when comparing Examples 11 to 14 with Examples 17 to 18, the average grain size of the sprayed film in Example 17 and the planular ratio of the grain in Example 18 were out of the preferable range, so that it was also confirmed that the performances of Examples 17 to 18 were relatively lowered.

Furthermore, when observed the cross sectional area of 0.0567 mm² in the respective sprayed films of Examples 11 to 18, the number of particles each having a planular ratio (Y/X) of 0.25 to 1.5 was all two or more in any cases. In contrast, a grain boundary could not be confirmed in the sprayed films of Comparative Examples 5 to 6.

### INDUSTRIAL APPLICABILITY

As has been explained above, according to the vacuum depositing apparatus parts and the vacuum depositing apparatus using the parts of the present invention, a sprayed film is formed to a part constituting the vacuum depositing apparatus, and a surface roughness of the sprayed film is controlled to be within a predetermined range, so that there can be effectively prevented a particle generation caused by peeling-off of the adhered film adhered to parts constituting the vacuum depositing apparatus whereby it becomes possible to decrease a manufacturing cost of the film products, and improve a production yield of the film products.

1. A vacuum depositing apparatus part constituting a vacuum depositing apparatus for depositing a thin film forming material vaporized in a vacuum chamber on a substrate, the vacuum depositing apparatus part comprises: a part body; and a sprayed film integrally formed to a surface of the part body wherein said sprayed film has a surface roughness of 10 μm or less in terms of an arithmetical average surface roughness Ra.

2. The vacuum depositing apparatus part according to claim 1, wherein said sprayed film has a plurality of dimples formed to a surface of the sprayed film.

3. The vacuum depositing apparatus part according to claim 2, wherein said dimples have an average diameter of 50 to 300 μm.

4. The vacuum depositing apparatus part according to claim 2, wherein said dimples have an average depth of 5 to 30 μm.

5. The vacuum depositing apparatus part according to claim 1, wherein said sprayed film is made from any one of Cu, Al and Cu—Al alloy.

6. The vacuum depositing apparatus part according to claim 1, wherein said sprayed film has a structure including grains having an average grain size of 5 to 150 μm, and a relative density of the sprayed film is 75 to 99%.

7. The vacuum depositing apparatus part according to claim 6, wherein said grains of the sprayed film has a planular ratio (Y/X) of 0.25 to 1.5 when a transversal length of each grains with respect to a thickness direction of the sprayed film is assumed to be X while a longitudinal length of each grains with respect to a thickness direction of the sprayed film is assumed to be Y.

8. The vacuum depositing apparatus part according to claim 6, wherein at least two grains exist within a cross sectional area of 0.0567 mm² in a thickness direction of the sprayed film.

9. The vacuum depositing apparatus part according to claim 1, wherein said vacuum depositing apparatus part is used for a vacuum depositing apparatus for depositing Ti or compound thereof on a substrate thereby to form a thin film.

10. The vacuum depositing apparatus part according to claim 1, wherein said sprayed film has a thickness of 50 μm or more.

11. The vacuum depositing apparatus part according to claim 1, wherein a surface of the sprayed film is subjected to a plastic work.

12. The vacuum depositing apparatus part according to claim 11, wherein said plastic work is at least one of a ball shot treatment and a dry ice treatment.

13. The vacuum depositing apparatus part according to claim 1, wherein a duration time of said vacuum depositing apparatus part is 300 kWh or more in terms of integral power consumption when the vacuum depositing apparatus in which a material component is vaporized by colliding ion, which is electrically accelerated, with a thin-film forming material is used for forming the thin film by depositing the vaporized component on the substrate, and the duration time of the vacuum depositing apparatus part is defined as an integral power consumption required for a sputtering period capable of continuously performing a film forming operation until the thin-film forming material deposited onto the vacuum depositing apparatus part is peeled off.

14. A vacuum depositing apparatus comprising the vacuum depositing apparatus part according claim 1 which is used as a constitutional member for the vacuum depositing apparatus.

15. The vacuum depositing apparatus according to claim 14, wherein said vacuum depositing apparatus is a sputtering apparatus.
